(19) United States
(12) Patent Application Publication
(10) Pub. No.: US 2025/0212699 A1
(43) Pub. Date: Jun. 26, 2025

(54) QUANTUM DEVICE WITH STACKED QUBITS

(71) Applicant: COMMISSARIAT A L'ENERGIE ATOMIQUE ET AUX ENERGIES ALTERNATIVES, Paris (FR)

(72) Inventor: Heimanu NIEBOJEWSKI, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/990,694

(22) Filed: Dec. 20, 2024

(30) Foreign Application Priority Data
Dec. 22, 2023 (FR) FR2315156

(51) Int. Cl. H10N 60/10; B82Y 10/00; H10N 60/01

(52) U.S. Cl. CPC H10N 60/128; H10N 60/01; H10N 60/11; B82Y 10/00

(57) ABSTRACT

A quantum electronic device provided with:

a first set of semiconductor regions (102L, 104L) comprising a first lower semiconductor region (102L) and a first upper semiconductor region (104L), superimposed on, and separated from, the first lower semiconductor region via a first dielectric ‘separation’ zone (ZS1),

a second set of semiconductor regions (102R, 104R) comprising a second lower semiconductor region (102R) and a second upper semiconductor region (104R), superimposed on, and separated from, the first lower semiconductor region via a second dielectric “separation” zone (ZS2),

the first set of semiconductor regions (102L, 104L) being disposed opposite the second set of semiconductor regions (102R, 104R),

at least one dielectric region (RD) separating the first set of semiconductor regions (102R, 104R) from the second set of semiconductor regions (102R, 104R).

### TECHNICAL FIELD AND STATE OF PRIOR ART

The present application is directed to the field of quantum devices in which at least one piece of information based on a given quantum state out of at least two measurable levels is used as an information vector. This quantum state is referred to as qubit or quantum bit.

One particular type of qubit is the spin qubit when the intrinsic degree of freedom of the spin of individual electrons is used for coding the quantum information.

Qubits can be formed in a semiconductor material within nano-sized electrostatically and/or physically defined confinement structures. These confinement structures are typically referred to as “quantum dots”.

A quantum dot behaves like a potential well confining one or more elementary charges (electrons or holes) in a semiconductor region.

To measure the state of a qubit, proceeding with a spin/charge conversion that makes it possible to convert the spin state of the charged particles into a state of charge of the quantum dots containing said particles is known. It is then necessary to measure this state of charge in order to deduce therefrom the spin state of the charged particles before conversion. For this, a means of measuring the state of charge is generally disposed facing or in proximity to each quantum dot.

A qubit can in particular be read using another quantum dot referred to as a “reading island” or “detection island” coupled to that of the qubit intended to be read. These two elements form two potential wells separated by a potential barrier.

Devices in which the detection islands and quantum dots are disposed facing each other and in a same plane parallel to the main plane of a substrate on which the quantum dots and detection islands are formed are known.

Document by R Pillarisetty “High Volume Electrical Characterization of Semiconductor Qubits”, 2019 IEEE International Electron Devices Meeting (IEDM) provides, for example, a device with quantum dots formed in a first elongate semiconductor block (“fin”) and detection islands formed in a second elongate semiconductor block parallel to the first block.

A problem arises as to producing a new quantum device that is preferably improved in terms of integration density while retaining good detection sensitivity.

### DESCRIPTION OF THE INVENTION

According to one aspect, the present invention relates to a quantum electronic device with a substrate, the substrate being coated with:
a first set of semiconductor regions comprising at least one first lower semiconductor region and at least one first upper semiconductor region, superimposed on and separated from the first lower semiconductor region by a first so-called “separation” zone, of dielectric material,
a second set of semiconductor regions comprising at least one second lower semiconductor region and at least one second upper semiconductor region, superimposed on and separated from the second lower semiconductor region by a second so-called “separation” zone, of dielectric material,
the first set of semiconductor regions being disposed opposite the second set of semiconductor regions so that the first lower semiconductor region is disposed facing the second lower semiconductor region and so that the first upper semiconductor region is disposed facing the second upper semiconductor region,
at least one dielectric region separating the first set of semiconductor regions from the second set of semiconductor regions.

The dielectric region can be provided so as to allow electrostatic coupling between the first lower semiconductor region and the second lower semiconductor region, and so as to allow electrostatic coupling between the first upper semiconductor region and the second upper semiconductor region,

Alternatively or in combination, the separation zones may also be provided so as to allow electrostatic coupling between the first lower semiconductor region and the first upper semiconductor region, and so as to allow electrostatic coupling between the second lower semiconductor region and the second upper semiconductor region.

With such a device, an improved qubit density is achieved while maintaining proximity between quantum dot and detection island, enabling good detection sensitivity to be retained.

Advantageously, the device may further comprise:
a first group of superimposed gates comprising at least a first lower gate and a first upper gate superimposed on and separated from the first lower gate via a first insulation zone, the first lower gate and the first upper gate being disposed against and facing the first lower semiconductor region and the first upper semiconductor region respectively so as to exert electrostatic control of the first lower semiconductor region and the first upper semiconductor region respectively,
a second group of superimposed gates comprising at least one second lower gate separated from a second upper gate superimposed on, and separated from, the second lower gate via a second insulation zone, the second lower gate and the second upper gate being disposed against, and facing, respectively the second lower semiconductor region and of the second upper semiconductor region so as to exert electrostatic control of the second lower semiconductor region and of the second upper semiconductor region respectively, the first group of superimposed gates and the second group of superimposed gates being disposed on either side of the first set of semiconductor regions and of the second set of semiconductor regions.

Advantageously, the first lower semiconductor region and the first upper semiconductor region are regions of a lower semiconductor bar and an upper semiconductor bar respectively, the lower semiconductor bar and the upper semiconductor bar extending in parallel to a first direction parallel to a main plane of the substrate, the device being provided with a third group of superimposed gates juxtaposed to said first group of superimposed gates and dedicated to the electrostatic control of a third lower semiconductor region of the lower semiconductor bar and a third upper semiconductor region of the upper semiconductor bar.

According to one possible implementation, said lower semiconductor bar and said upper semiconductor bar are a first lower semiconductor bar and a first upper semiconductor bar, respectively, the second lower semiconductor region and the second upper semiconductor region being regions of a second lower semiconductor bar and a second upper semiconductor bar, respectively, said second lower and upper semiconductor bars extending in parallel to said first lower and upper semiconductor bars, respectively, the device having a fourth group of superimposed gates juxtaposed to said second group of superimposed gates for electrostatic control of a fourth semiconductor region of the second lower semiconductor bar and a fourth upper semiconductor region of the second upper semiconductor bar, the first lower semiconductor bar and the second lower semiconductor bar being located in a same first plane parallel to a principal plane of the substrate, the first upper semiconductor bar and the second upper semiconductor bar being located in a same second plane parallel to a main plane of the substrate, the third lower semiconductor region being disposed facing the fourth lower region, the third upper semiconductor region being disposed facing the fourth upper semiconductor region.

According to one possible implementation, the device can further comprise, in a direction parallel to the first direction, between said first group of gates and said third group of gates:
at least one exchange electrode or,
superimposed exchange electrodes separated from each other by an insulating separation layer,
a zone of at least one insulating material.

According to one advantageous embodiment, the device may further comprise:
a doped semiconductor block, forming a first dopant reservoir, the doped semiconductor block being arranged at a first end of the first upper semiconductor bar, the first lower semiconductor bar, the second upper semiconductor bar and the second lower semiconductor bar,
another doped semiconductor block, forming a second dopant reservoir, the other doped semiconductor block being arranged at a second end of the first upper semiconductor bar, the first lower semiconductor bar, the second upper semiconductor bar, the second lower semiconductor bar, and which is opposite to the first end.

According to one particular embodiment, the dielectric region between the first set of semiconductor regions and the second set of semiconductor regions is provided with a heterogeneous dielectric composition such that in a central portion located between the first lower semiconductor region and the second upper semiconductor region and between the first upper semiconductor region and the second lower semiconductor region, the dielectric region has a first composition and a first relative dielectric permittivity, and in another portion located between the first lower semiconductor region and the second lower semiconductor region or between the first upper semiconductor region and the second lower semiconductor region, the dielectric region has a second composition and a second relative dielectric permittivity higher than the first relative dielectric permittivity.

According to one possible arrangement of this particular embodiment, the dielectric region with heterogeneous dielectric composition between the first set and the second set of semiconductor regions can be formed of:
said central portion of a first dielectric material having a first dielectric constant,
a lower portion located between the first lower semiconductor region and the second lower semiconductor region of a second dielectric material having a second dielectric constant lower than the first dielectric constant,
an upper portion located between the first upper semiconductor region and the second upper semiconductor region of a second dielectric material having a second dielectric constant lower than the first dielectric constant, the lower portion, the central portion and the upper portion being superimposed.

According to a second possible arrangement of this particular embodiment, the dielectric region with heterogeneous insulating composition between the first set and the second set of semiconductor regions is formed of:
at least one dielectric material having a dielectric constant k2 lining each of the first and second lower and upper semiconductor regions, so as to form lower insulating bumps against the first and second lower semiconductor regions and upper bumps against the first and second upper semiconductor regions, and hollow parts each between an upper insulating bump located on the first or second upper semiconductor region and a lower insulating bump located on the first or second lower semiconductor region.
an insulating space arranged formed between the insulating bumps and by the hollow portions, said insulating space being filled with another dielectric material having a dielectric constant k1, such that k1<k2, or being empty.

According to another aspect, the present invention relates to a method for making a quantum electronic device and in particular a quantum device as defined above.

An embodiment provides a method for manufacturing a quantum device as defined above wherein forming said first set of semiconductor regions and said second set of semiconductor regions comprises steps of:
making on said substrate a structure formed by a superimposition of layers comprised of alternating layers based on a first given material and layers based on a second material, the second material being semiconducting, said first given material being able to be etched selectively with respect to said second given material,
making a separation trench mainly extending in a direction parallel to the first direction by etching said superimposition of layers so as to divide said structure into a first portion and a second portion, the first portion and the second portion extending in parallel to the first direction, the semiconductor regions of said first set being semiconductor regions of the first portion and formed based on said second given material, the semiconductor regions of said second set being semiconductor regions of the second portion and formed based on said second given material.

Advantageously, after making said trench, the method may comprise forming said dielectric region by depositing dielectric material between said first portion and said second portion of said structure.

According to one possible implementation, after making the separation trench and prior to forming said dielectric region, the method may comprise steps of:
at least partially etching said first material and selectively with respect to the second material in the first portion and said second portion so as to release spaces,
filling said spaces with a dielectric material so as to form the first “separation” zone and the second “separation” zone.

According to an embodiment, after filling said spaces with a given dielectric material, the method may comprise steps of:
anisotropically etching the dielectric material so as to release a space forming a reduced trench between said portions of active zone,
filling the reduced trench by means of at least one other dielectric material different from said given dielectric material.

Advantageously, the method for manufacturing the quantum device may further comprise, after forming said structure and prior to forming said separation trench in said structure, steps of:
forming gate patterns of gate material on either side of the structure,
forming an insulating encapsulation around the gate patterns,
partially removing the gate material so as to retain a lower block (GI) of gate material and making cavities above this lower block of gate material and that are surrounded by the encapsulation,
filling the cavities with at least one insulating layer so as to form an insulation zone on the lower block of gate material and then,
filling the cavities with at least one layer of gate material, so as to form an upper block of gate material over the insulation zone.

Advantageously, the manufacturing method may further comprise,
after forming said structure and prior to forming said separation trench in this structure, forming dopant reservoirs at ends of said structure, forming said dopant reservoirs comprising:
performing partial selective etching of the first material with respect to the second material in order to create recesses at said ends of said structure,
filling said recesses with an insulating material in order to form insulating plugs in said recesses,
performing epitaxy of semiconductor material from uncovered ends of the layers based on the second material, while the layers based on the first material are protected by the insulating plugs.

### BRIEF DESCRIPTION OF THE DRAWINGS

The present invention will be better understood upon reading the description of exemplary embodiments provided merely for illustrative purposes and which are in no way limiting, with reference to the appended drawings wherein:

FIG. 1 illustrates an example of a quantum device according to the invention with several levels of superimposed semiconductor regions.

FIG. 2A illustrates an exemplary embodiment wherein the quantum device has a plurality of superimposed gate pairs distributed along superimposed semiconductor bars.

FIG. 2B illustrates a superimposition of semiconductor bars in the quantum device.

FIGS. 3 and 4 illustrate an exemplary embodiment of the quantum device wherein an insulating space is provided between groups of adjacent gates distributed along superimposed semiconductor bars.

FIGS. 5, 6A and 6B illustrate an exemplary embodiment of a semiconductor structure of active region for a quantum device with two sets of superimposed semiconductor regions.

FIGS. 7 to 9 illustrate an exemplary embodiment of gate patterns.

FIGS. 10 to 13 illustrate an exemplary embodiment of dopant reservoirs.

FIGS. 14 to 19 illustrate an exemplary embodiment of superimposed gates from gate patterns.

FIGS. 20A and 20B illustrate an exemplary embodiment of a separation trench to separate a semiconductor structure of active zone into distinct portions arranged face to face with each other and including superimposed semiconductor regions.

FIGS. 21 and 22 illustrate an exemplary embodiment of dielectric separation zones sandwiched between superimposed semiconductor regions of the portions of the structure of active zone.

FIGS. 23A and 23B illustrate an exemplary embodiment of an intermediate dielectric region between a first portion and a second portion of a structure of active zone.

FIG. 24 illustrates a first particular embodiment of the quantum device in which the intermediate dielectric region has a heterogeneous composition in order to allow electrostatic coupling between semiconductor regions of the first portion and of the second portion situated in a same level while preventing electrostatic coupling between, on the one hand, semiconductor regions of the first portion and, on the other hand, semiconductor regions of the second portion situated in different levels.

FIGS. 25 to 29 illustrate an exemplary method for manufacturing the first particular embodiment of a quantum device.

FIGS. 30, 31, 35, 39 and 40 illustrate a second particular embodiment of the quantum device.

FIGS. 32 to 34 illustrate a first exemplary method for manufacturing the second particular exemplary embodiment of quantum device.

FIGS. 36 to 39 illustrate an exemplary method for manufacturing the second particular embodiment of the quantum device.

FIGS. 41 and 42 illustrate an exemplary embodiment of exchange gates.

Identical, similar or equivalent parts of the different figures bear the same reference numerals so as to make it easier to switch from one figure to another.

The different parts represented in the figures are not necessarily drawn to a uniform scale, to make the figures more legible.

In addition, in the following description, terms which depend on the orientation of the structure such as “above”, “below”, “lower”, “upper”, “juxtaposed”, “superimposed” apply on the assumption that the structure is oriented as illustrated in the figures.

### DETAILED DESCRIPTION OF PARTICULAR EMBODIMENTS

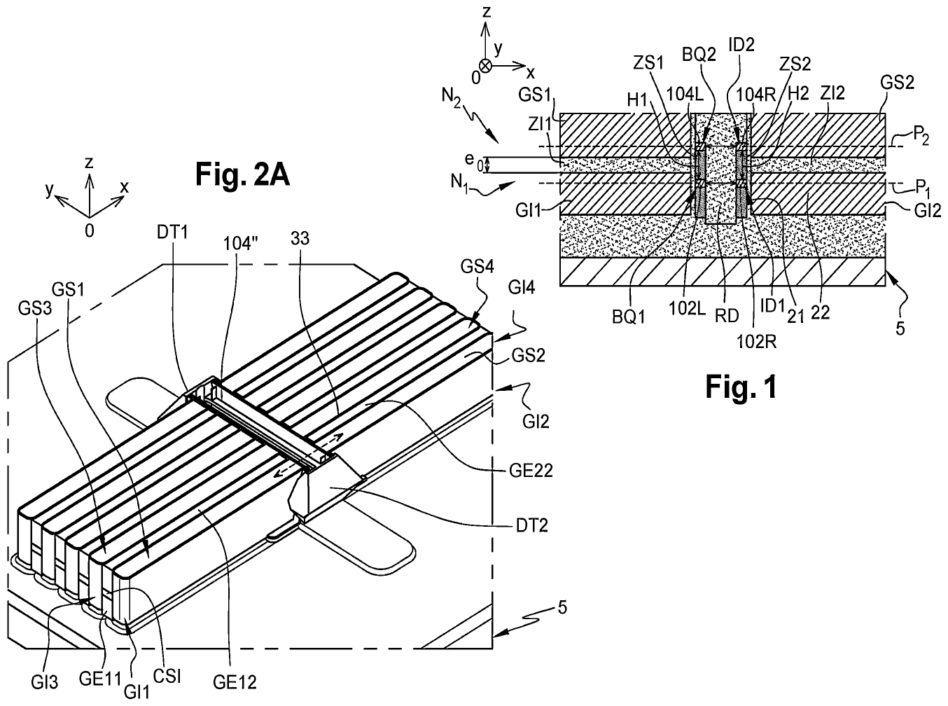

FIG. 1 is firstly referred to as an exemplary embodiment of a quantum device.

The device is arranged on a substrate 5, which may be, for example, of the semiconductor-on-insulator type, in particular of the SOI type or of the bulk type, for example of silicon.

The device is herein provided with quantum dots BQ1, BQ2 formed in a first set of superimposed semiconductor regions 102L, 104L, for example of silicon or germanium. A quantum dot BQ1 is thus made in a first so-called “lower” semiconductor region 102L, while another quantum dot BQ2 disposed above the first lower semiconductor region is formed in a first so-called “upper” semiconductor region 104L.

The quantum dots BQ1 and BQ2 each confine at least one elementary charge (electron(s) or hole(s)). Preferably, each quantum dot BQ1, BQ2 herein includes a single elementary charge. The spin of this charge in particular an electron, can be provided for coding the quantum information. In this case, the qubits associated with quantum dots BQ1 and BQ2 are spin qubits.

To enable detection of a quantum state also referred to as ‘state of charge’ of the quantum dots BQ1, BQ2, a charge detection structure is provided in proximity and in this example in front of the quantum dots BQ1, BQ2.

This detection structure comprises detection islands ID1, ID2 formed in a second set of superimposed semiconductor regions 102R, 104R, typically based on a same semiconductor material as the regions 102L, 104L. A detection island ID1 is thus made in a second lower semiconductor region 102R which faces the first lower semiconductor region 102L, while another detection island ID2 is formed in a second upper semiconductor region 104R disposed above the second lower semiconductor region 102R and faces the first upper semiconductor region 104L.

The first semiconductor regions 102L, 104L are thus each designed to form a qubit, while the second semiconductor regions 102R, 104R are dedicated to reading the qubits.

In the particular exemplary embodiment illustrated, the lower semiconductor regions 102L, 102R are arranged in a same first plane P1, while the upper semiconductor regions 104L, 104R are arranged in a same second plane P2, the first and second planes P1 and P2 being parallel to a main plane of the substrate 5 (i.e. a plane defined throughout the description as a plane passing through the substrate 5 and which is parallel to the plane [0; x; y] of the orthogonal reference frame [0; x; y; z]).

The device is also provided with at least one dielectric region RD based on at least one dielectric material located between, on the one hand, the superimposition of quantum dots BQ1, BQ2 and, on the other hand, the superimposition of islands ID1, ID2.

In this exemplary embodiment, the operation of the device is based on capacitive coupling, also referred to as ‘electrostatic coupling’, between each quantum dot BQ1, BQ2 and a detection island ID1, ID2 arranged opposite the quantum dot BQ1, BQ2. In this case, the dielectric material(s) of the dielectric region RD are selected in particular in terms of relative permittivity or dielectric constant and the dimensions D1, D2 (corresponding respectively to the distance between upper semiconductor regions and the distance between lower semiconductor regions) of this dielectric region RD for achieving such electrostatic coupling. Such coupling can result in a measurable useful signal which is greater than a parasitic signal and which can be in the order of several fF (femto Farad).

For example, for achieving electrostatic coupling between a quantum dot and an island facing this dot, the dielectric region RD can be formed from SiO₂, SiN, Al₂O₃, HfO₂, and with dimensions D1, D2 of between 10 nm and 60 nm, for example, advantageously between 20 nm and 40 nm.

For achieving electrostatic control of quantum dots and detection islands, provision is made for gates formed by a conductive or semiconductive block of gate material 22, for example polysilicon, against a dielectric gate layer 21 disposed between the gate block and the semiconductive regions. The arrangement provided in FIG. 1 herein has the feature of providing a same gate dielectric layer 21 common to the two superimposed gates GI1, GS1 and semiconductor regions 102L, 104L.

The quantum dots BQ1, BQ2 are controlled by a first group of superimposed gates GI1, GS1, each gate GI1, GS1 being herein disposed against a quantum dot BQ1, BQ2. A first so-called “lower” gate GI1 for electrostatic control of the first lower semiconductor region 102L is located in the first plane P1, while a first so-called “upper” gate GS1 for electrostatic control of the first upper semiconductor region 104L is located in the second plane P2.

The first upper gate GS1 is superimposed on and separated from the first lower gate GI1 via a first insulation zone ZI1. This first zone of insulation ZI1 between the lower GI1 and upper GS1 gates is typically of insulating material and preferably of sufficient thickness e₀ to electrically insulate the gates GI1, GS1 from each other. For example, the first insulating zone ZI1 is formed from SiO₂ and has a thickness e₀ which may be between 5 nm and 20 nm, for example.

For achieving electrostatic control of semiconductor regions 102R, 104R, a second group of superimposed gates GI2, GS2 is provided, each gate GI2, GS2 being herein juxtaposed against a semiconductor region 124a, 124b. A second lower gate GI2 is located in the first plane P1, while a second upper gate GS2 is located in the second plane P2 and insulated from the lower gate GS2 via an insulation zone ZI2. This second insulation zone ZI2 of the lower GI2 and upper GS2 gates is advantageously provided with a thickness and material similar to that of the first insulation zone ZI1.

In this exemplary embodiment, there is thus advantageously an alignment of the lower gates GS1, GR1 and the lower semiconductor regions 102L, 102R in a same plane P1 and an alignment of the upper gates GS2, GR2 and the upper semiconductor regions 104L, 104R in a same upper plane P2 distinct from the plane P1.

According to one possible implementation of the device, it can be provided that each qubit stage is independent of the other stages, thus preventing electrostatic coupling between the first lower semiconductor region 102L and the first upper semiconductor region 104L. Electrostatic coupling between the second lower semiconductor region 102R and the second upper semiconductor region 104R is then also typically prevented. In this case, only horizontal interactions (in other words in directions parallel to the main plane of the substrate) between quantum dots BQ1, BQ2 and detection islands ID1, ID2 are promoted.

To enable the lower stage to be insulated from the upper stage, so-called ‘separation’ zones ZS1, ZS2 arranged respectively between the first lower and upper semiconductor regions 102L and 104L and between the second lower and upper semiconductor regions 102R and 104R are provided, herein preferably of dielectric material, for example SiO₂, and with a sufficient thickness (also referred to as height) H1, H2, for example of at least 30 nm, and typically of between 30 nm and 100 nm.

It can be envisaged to integrate several other quantum dots in the lower stage N₁ in which quantum dot BQ1 is located and several other quantum dots in the upper stage N2 in which quantum dot BQ2 is located. In this case, the first lower semiconductor region 102L may be a region of a semiconductor block typically in the form of a bar (cross-section view in FIG. 1), for example parallelepipedal or substantially parallelepipedal in shape and referred to as the first lower semiconductor bar, in which other semiconductor regions forming other quantum dots each controlled by a gate are arranged.

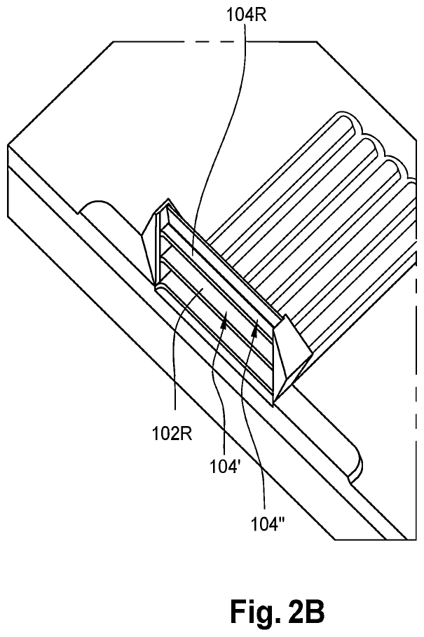

Similarly, the first upper semiconductor region 104L may be formed in another semiconductor bar referred to as the first upper semiconductor bar in which other semiconductor regions forming other quantum dots each controlled by a gate are arranged. The second lower semiconductor region 102R may be a region of a second lower semiconductor bar located in the same first plane P1 as the first lower semiconductor bar and in which other semiconductor regions forming other detection islands each controlled by a gate are arranged. Similarly, the second upper semiconductor region 104R may be formed in a second upper semiconductor bar in which other semiconductor regions forming other detection islands each controlled by a gate are disposed. A partial perspective view given in FIG. 2B serves to illustrate a superimposition of bars 104′, 104″ in which the second upper semiconductor region 104R and the second lower semiconductor region 102R are formed respectively.

The first and second lower and upper semiconductor bars all extend in a first direction (direction orthogonal to the plane of FIG. 1 and parallel to the axis y of the orthogonal reference frame [0; x; y; z]).

As can be seen from the exemplary embodiment illustrated in

FIG. 2A (where the dielectric region RD is not represented for more legibility and only the second upper bar 104″ is visible) other groups of superimposed gates can be provided to control a lower and upper row of quantum dots as well as a lower and upper row of detection islands. The different groups of gates are distributed in the first direction along the bars and the gates typically extend in a second direction orthogonal to the first direction (and parallel to the axis x of the orthogonal reference frame [0; x; y; z]).

Gates GI3, GS3 of a third group of superimposed gates, juxtaposed to the first group of superimposed gates GI1, GS1 (FIG. 2A) are thus dedicated to electrostatic control of, respectively, a third lower semiconductor region of the first lower semiconductor bar and a third upper semiconductor region of the first upper semiconductor bar. A fourth group of superimposed gates GI4, GS4 juxtaposed to the second group of superimposed gates GI2, GS2 is herein also provided, to control respectively a fourth lower semiconductor region of the second lower semiconductor bar and a fourth upper semiconductor region of the second upper semiconductor bar.

Advantageously, the device can be further provided with dopant reservoirs DT1 and DT2 at the ends of the lower and upper rows of quantum dots and detection islands. These dopant reservoirs can be in the form of blocks, typically of doped semiconductor material, for example phosphorus-doped silicon or boron-doped silicon germanium. In the particular exemplary embodiment illustrated, each block forming a dopant reservoir DT1, DT2 is connected to one end of the set of semiconductor bars.

Advantageously, exchange electrodes GE11, GE12, GE22 also referred to as ‘exchange gates’ can be provided in inter-gate spaces. In the particular exemplary embodiment of FIG. 2A, rather than a single exchange electrode in a same inter-gate space, a pair of exchange electrodes GE11, GE12 superimposed in a same inter-gate space is advantageously provided.

The exchange electrodes GE11, GE12 mainly extend in a direction parallel to that in which the gates GI1, GS1, GI3, GS3 extend and which is preferably orthogonal to the first direction (the first direction being parallel to the axis y), in other words to the direction in which the semiconductor bars accommodating the detection islands and quantum dots extend. Each exchange electrode is typically separated from adjacent gates via an insulating spacer layer 33.

The arrangement of the exchange electrodes GE11, GE12 can be similar to that of the gates GS3, GI3 or GS1, GI1, so that an upper exchange electrode GE12 is disposed above a lower exchange electrode GE11 and insulated from this lower exchange electrode GE11 by the insulating layer an insulating separation layer CSI. The exchange electrodes achieve charge exchange between neighbouring quantum dots or between neighbouring detection islands distributed along a same semiconductor bar. Thus the exchange electrode GE11 enables charge exchange between a first lower semiconductor region controlled by the gate GI1 and a lower semiconductor region controlled by the gate GI3 and located on a same semiconductor bar as the first lower semiconductor region.

The implementation of exchange electrodes is optional, in particular when the pitch Δ of the gates is small, for example less than 40 nm. In this case, some of the gates can be used to control exchange between adjacent quantum dots or detection islands of a same semiconductor portion.

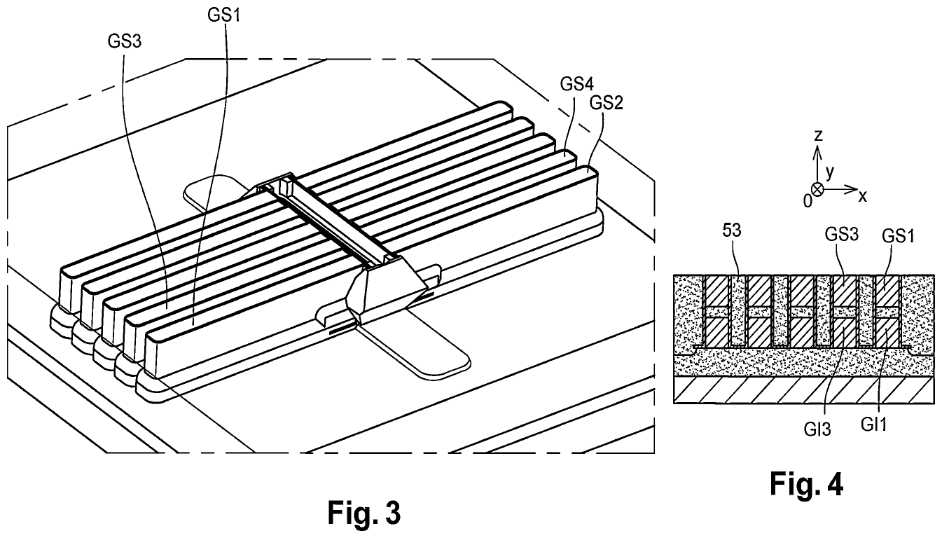

Thus, in an alternative embodiment illustrated in FIGS. 3 and 4, the inter-gate spaces are devoid of exchange electrodes.

In FIG. 4, which shows a transverse cross-section view of the gates GI1, GS1, GI3, GS3 (in other words, along a sectional plane orthogonal to the direction in which the gates extend), the inter-gate spaces are filled with insulating material 53.

In either of the exemplary embodiments just given, the device comprises two levels or stages N1, N2 of quantum dots and detection islands. However, the quantum device is not limited to this number and can integrate a higher number k (with k>2) of stages. Thus, more generally, a quantum device as implemented according to the invention can comprise a number of superimposed semiconductor region stages greater than two.

As an alternative to either of the previously described exemplary embodiments in which horizontal interactions between quantum dot BQ1 (or BQ2) and detection island ID1 (or ID2) are implemented, a device with both horizontal and vertical interactions between different levels of semiconductor regions may be provided. In this case, in particular, the separation zones ZS1, ZS2 illustrated in FIG. 1 can be provided with heights H1, H2 sufficiently low and based on a dielectric material with a sufficiently high dielectric constant to allow electrostatic coupling between the first lower semiconductor region 102L and the first upper semiconductor region 104L as well as between the second upper semiconductor region 102R and the second upper semiconductor region 104R. For example, for achieving electrostatic coupling between an upper semiconductor region 104L, 104R and a lower semiconductor region 102L, 102R, below, the separation zones ZS1, ZS2 can be formed based on high-k material (in other words with a high dielectric constant k), for example HfO₂, with a height H1, H2 of between 10 nm and 30 nm, for example, advantageously between 10 nm and 20 nm.

The capacitance, which is a measurable value, between 104L and 102L is greater than the capacitance measured between 104L and 104R.

A quantum device as described previously can adapt to different types of reading circuits. For example, it adapts to a transport reading circuit where the quantum state of a quantum dot is read by measuring current in the detection island associated therewith. It also adapts to a reading circuit operating by reflectometry in which an RF signal is emitted in the direction of the detection island and then a reflected RF signal is detected in order to deduce the state of charge of a quantum dot associated with this detection island.

According to another possible implementation of the device, a purely vertical coupling between semiconductor regions of different levels. Thus capacitive coupling is implemented between a first semiconductor region of a lower or higher level forming a quantum dot and another semiconductor region of a different level forming a detection island, whereas such coupling is prevented between semiconductor regions of the same level or located in a same plane. In this case, for example, the separation zones ZS1, ZS2 are provided in terms of dimensions H1, H2 and the dielectric material from which they are formed so as to allow electrostatic coupling between the first lower semiconductor region 102L and the first upper semiconductor region 104L, and so as to allow electrostatic coupling between the second lower semiconductor region 102R and the second upper semiconductor region 102L. The dielectric region RD can then be provided in terms of dimensions D1, D2 and the dielectric material making up that dielectric region, so as to prevent electrostatic coupling between the first lower semiconductor region 102L and the second lower semiconductor region 102R and also to prevent electrostatic coupling between the first upper semiconductor region 104L and the second upper semiconductor region 104R.

A quantum device as provided according to one or more of the previously described modes can be implemented using a thin-film microelectronic manufacturing method.

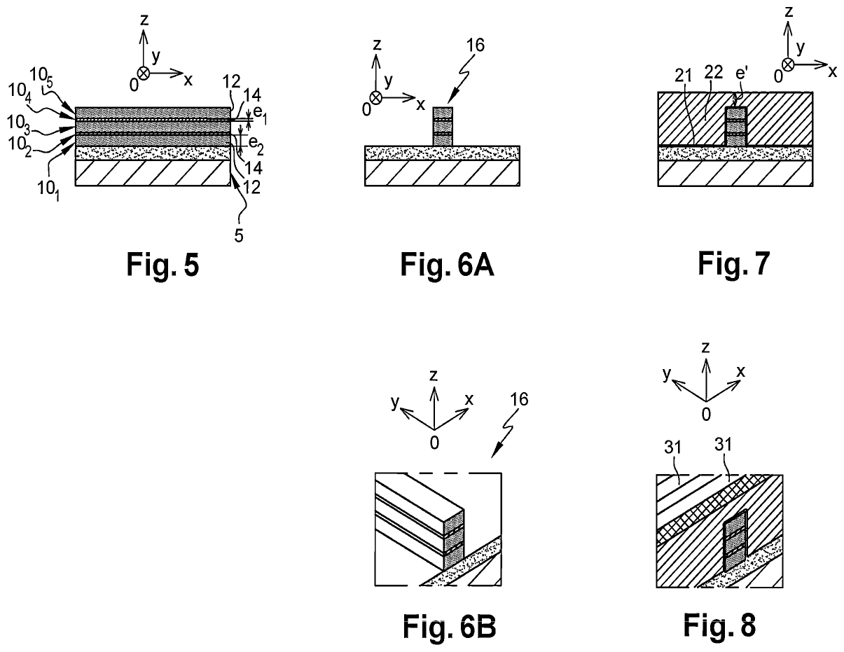

FIG. 5 is firstly referred to, and gives an example of a possible starting structure for making a quantum device according to the invention, herein including a substrate 5 which may be of the semiconductor-on-insulator type, for example SOI, or of the bulk type, for example of silicon.

A stack of layers formed by alternating layers 10₁, 10₃, 10₅ of a first material 12 and layers 10₂, 10₄ of a second material 14 is made on the substrate 5. The materials 12, 14 are typically different semiconductor materials, the first material 12 being able to be etched selectively with respect to the second material 14. The particular exemplary embodiment illustrated in FIG. 5 provides for an odd number of layers, in particular five layers, but the method can be performed with a different and in particular higher number of layers.

The layers 10₁, 10₃, 10₅ based on the first material 12 can advantageously be made with a thickness greater than that of the layers 10₂, 10₄ based on the second material 14, and which can be, for example, more than twice that of the layers 10₂, 10₄. The layers 10₁, 10₃, 10₅ based on the first material 12 can have a thickness e₁ of, for example, between 10 nm and 50 nm, while the layers 10₂, 10₄ have a thickness e₂ of, for example, between 5 nm and 20 nm.

For example, the first material 12 is silicon while the second material 14 is Si₁₋ₓGeₓ, with x>0, x being, for example, in the order of 30%. The layers 10₁, 10₃, 10₅, 10₂, 10₄ can be made by successive epitaxies.

When the first layer 10₁ is SiGe, this layer can optionally be formed from a surface layer of silicon on an SOI substrate by a Germanium enrichment method known to those skilled in the art, which consists in performing silicon epitaxy and then carrying out oxidation in order to diffuse germanium. Etching is then made so as to remove the oxide formed.

Then (FIGS. 6A and 6B), by etching the stack of layers 10₁, 10₂, 10₃, 10₄, 10₅, a structure of active zone 16 is defined, herein in the form of a block, typically oblong in shape, for example parallelepipedal, and which mainly extends in a first direction (direction orthogonal to the plane of FIG. 1 and parallel to the axis y of the orthogonal reference frame [0; x; y; °z]). This can be made by photolithography and etching the stack. Dry etching using fluorocarbon chemistry through a lithography mask (not represented) can be carried out for this purpose.

Gate patterns 25 are then formed from gate material 22 on either side of the structure 16.

For this, at least one layer 21 of at least one gate dielectric is first deposited, for example of silicon oxide (SiO₂) or formed of a stack of silicon oxide and a high-k material such as HfO₂ for example. This deposition is followed by that of at least one layer of conductive gate material 22, such as doped polysilicon (FIG. 7).

Preferably, after deposition and possible planarisation by CMP, a non-zero thickness e′ of conductive material 22, for example in the order of 50 nm, is left to protrude from the structure 16 of active zone.

Hard masks 31, typically dielectric and for example formed from a stack of SiN and SiO₂, are then made (FIG. 8).

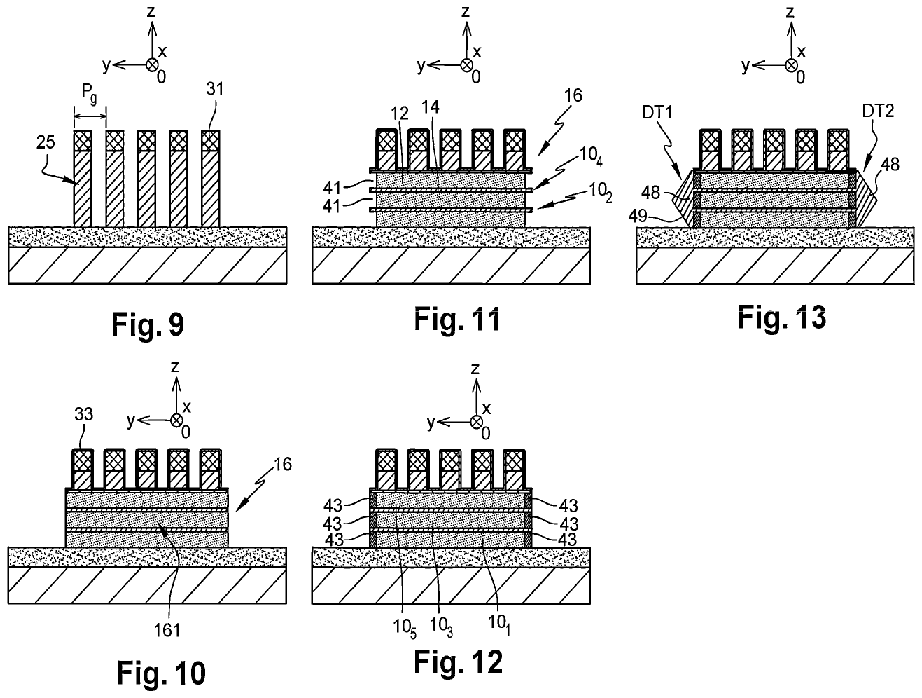

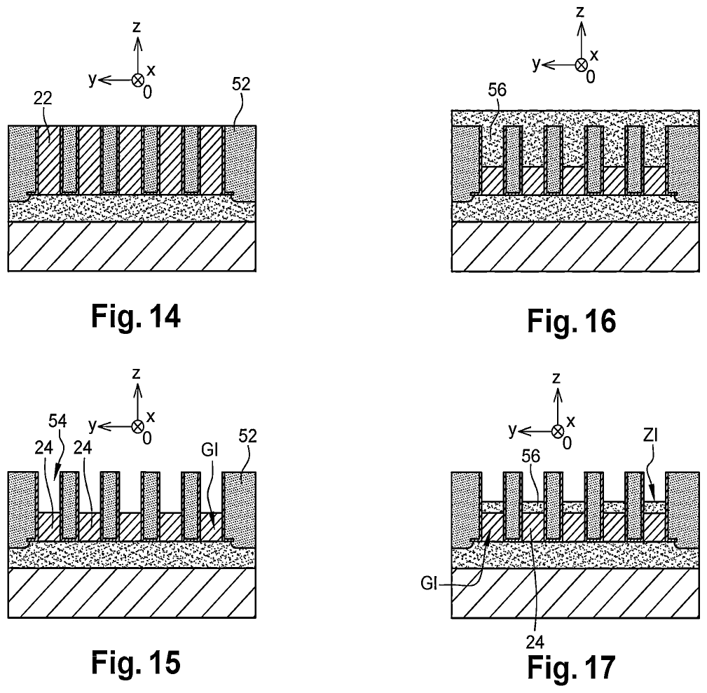

Then (FIG. 9 giving a cross-sectional view along a first plane parallel to reference [0°;y°;°z]) lithography and etching are carried out on the stack of gates to form an array of patterns 25 of parallel gates. The gate patterns 25 can be distributed at a small pitch Pg, for example in the order of 100 nm, or even smaller, for example 40 nm, to form a dense array of patterns 25.

After forming the gate patterns 25, dopant reservoirs DT1 and DT2 can advantageously be formed (FIGS. 10 to 13).

According to one method, a thin insulating spacer layer 33 is first conformally deposited on the gate patterns 25 (FIG. 10 giving a cross-sectional view along a second plane parallel to the reference point [0; y; z] and distinct from the first cross-sectional sectional plane of FIG. 9), for example of silicon nitride and of a thickness which may be between 5 nm and 10 nm, for example. The thin insulating spacer layer 33 is arranged on and between the gate patterns 25, for example by an ALD (Atomic Layer Deposition) technique, in order to fill the inter-gate spaces without creating a filling defect.

Lithography is then carried out so as to remove portions of the thin insulating spacer layer 33 and extend this etching into parts of the structure 16 of active zone located around another part 161 in vertical alignment with the set of gate patterns 25 (FIG. 10 giving a cross-section view along a second cross-sectional plane parallel to the reference [0; y; z] and different from the first cross-sectional plane).

In order to form the dopant reservoirs in contact with the semiconductor layers 10₂, 10₄ in which it is intended to form the quantum dots and detection islands without bringing these reservoirs into contact with the other layers 10₁, 10₃, 10₅ of the structure, partial etching of the first material 12 selectively with respect to the second material 14 can advantageously be performed in order to create recesses 41

(FIG. 11) at flanks of the structure 16. For example, when the first material 12 is SiGe, this etching is for example performed by wet chemical etching, or using HCl or a HF:H2O2:CH3COOH mixture. Removing of at least 5 nm, for example, can be provided to make these recesses 41. The recesses 41 are then filled with insulating plugs 43, also referred to as “inner spacers” (FIG. 12). This can be made, for example, by means of a conformal deposition of dielectric material, for example SiN or SiO₂. This deposition is typically followed by dry etching or a combination of dry and wet etching of the dielectric deposited, so as to form insulating plugs 43 blocking access to the layers 10₁, 10₃, 10₅ based on the first material 12.

Once the plugs 43 have been made, selective epitaxy of semiconductor material 48 can be performed from the uncovered ends of the layers 10₂, 10₄, based on the second material 14. Epitaxy can include in situ doping. For example, dopant reservoirs DT1, DT2 of Si:P or SiGe:B can be epitaxially formed from ends of silicon layers. The epitaxy formed may or may not follow preferred crystalline orientations, and the epitaxial fronts from the different Si layers may possibly meet, as in the exemplary embodiment represented in FIG. 13, to form semiconductor blocks or clusters 49.

Superimposed gates can then be formed.

For this, one method is to first make an insulating encapsulation 52 around the gate patterns. Insulating encapsulation 52 can be made, for example, by depositing a PMD-type material (“Pre Metal Dielectric”) such as SiO₂ over the entire structure, followed by a CMP planarisation step. This step is preferably carried out so that the polishing front stops at the top of the structure 16 of active zone. This enables the material 22 of the gate patterns to be uncovered, typically a conductive gate material such as polysilicon.

Then (FIG. 15) partial etching of the material 22 of the gate patterns is performed. Partially removing the gate material 22 is performed in such a way as to retain a lower block 24 of gate material and to make cavities 54 surrounded by the encapsulation 52 and disposed above this lower block 24 of gate material. Dry etching or chemical etching, in particular wet etching using TMAH (“Tetramethylammonium hydroxide”) is in particular implemented when the material 22 is polySi.

Etching is performed in such a way as to control the height of the lower block 24 of gate material relative to that of the semiconductor layers of the structure 16 of active zone. Partial removal is implemented so that this block 24 for forming a lower gate GI faces only a single layer 102 based on the second material 14, in particular the lower-level semiconductor layer for accommodating quantum dots or qubits.

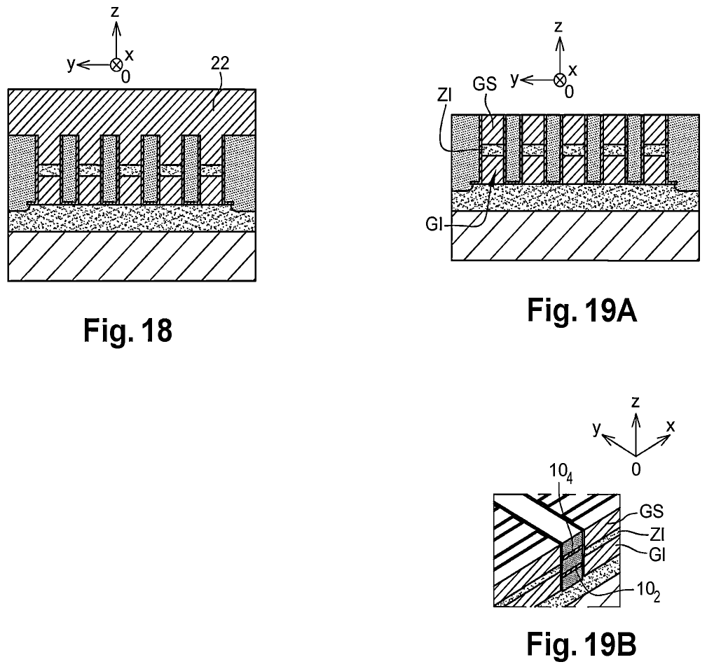

These cavities 54 are then filled (FIG. 16) with at least one layer of insulating material 56, for example SiO₂. This deposition is possibly followed by planarisation and etching to partially remove the insulating material 56 deposited (FIG. 17). The insulating material 56 serves to form an insulation zone ZI for insulating the stages of superimposed gates from each other. A new layer of conductive material, advantageously based on the same conductive material 22 as the lower gate GI, for example polysilicon, is then deposited (FIG. 18) so as to fill the cavities 54. Planarisation is then typically carried out using CMP (FIGS. 19A, 19B) to thus form an upper gate GS.

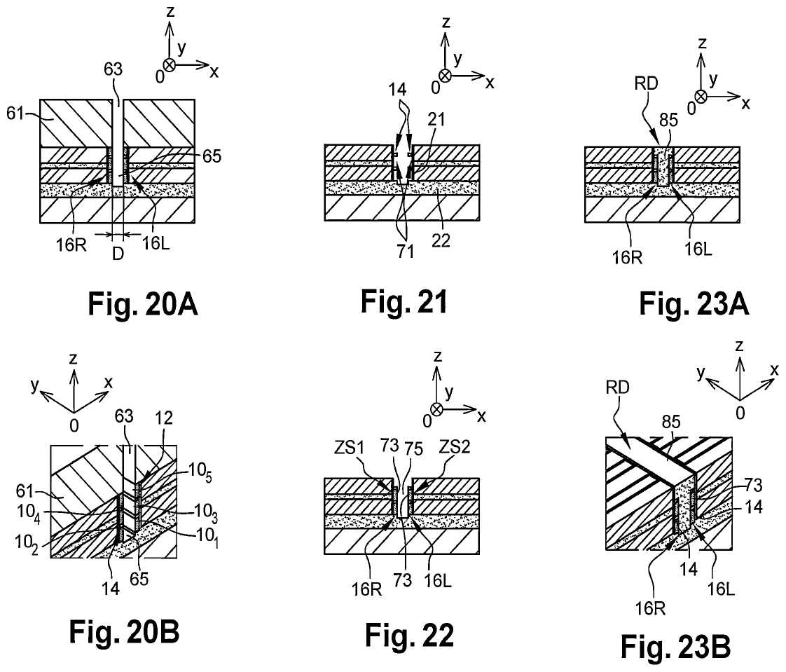

A separation trench 65 is then made (FIGS. 20A, 20B) in order to divide the structure 16 of active zone into two distinct portions 16R, 16L. The trench 65 is typically made until it reaches the substrate 5 through the opening 63 of a masking 61. The trench 65 mainly extends in a direction parallel to the given axis y in FIGS. 20A and 20B, also corresponding to the main direction in which the first portion 16A and the second portion 16B extend.

The masking 61 is for example formed on the basis of a lithographic resin stack typically comprising a photo-sensitive resin formed on an anti-reflective layer itself formed on a so-called “planarising” layer, typically organic and for example of the SOC (for ‘Spin-On-Carbon’) type. Etching the trench is typically anisotropic, for example using a fluorocarbon plasma.

According to one particular exemplary embodiment, the width D (dimension measured in parallel to the axis x in FIG. 20A) of the trench 65 corresponding to the distance between the portions 16R, 16L has a dimension of between 30 nm and 60 nm, for example in the order of 50 nm. This trench 65 results in obtaining two portions 16R, 16L facing each other, each formed of a same alternation of layers of a first material and a second material, for example SiGe and Si.

In the particular exemplary embodiment in which, rather than being based on an insulating material, a first semiconducting material 12 is used for the layers 10₁, 10₃, 10₅ of the stack on the basis of which the portions 16R, 16L are each formed, it may be provided to replace this semiconducting material 12 with a dielectric material in order to form zones of separation between the different levels of layers 10₂, 10₄ based on the second material 14.

Thus, in this case, removal of the layers 10₁, 10₃, 10₅ based on the first material 12 is first carried out (FIG. 21) by selective etching with respect to the second material 14. In the case where the first material 12 is SiGe and the second material 14 is silicon, this selective removal of SiGe in order to release silicon can be made by isotropically and selectively etching the SiGe layers, for example by wet-chemical etching using HCl or HF:H2O2:CH3COOH.

Spaces 71 between regions based on the second material 14 are thus released. The dopant reservoirs (not visible in FIG. 21) can then participate in maintaining the semiconductor regions based on the second material 14.

This is then filled with a dielectric material 73 to form insulating “separation” zones ZS1, ZS2.

The choice of dielectric material for the insulating zones ZS1, ZS2, made in particular in terms of the permittivity or dielectric constant of this material, depends on whether or not it is desired to promote coupling in the vertical direction (direction parallel to the axis z) between successive semiconductor stages of material 14 in the portions 16A, 16B.

The insulating zones ZS1, ZS2 are typically made by conformal deposition of dielectric material 73 and then anisotropic etching or a combination of anisotropic/isotropic etching(s) of this dielectric material 73 so as to retain this dielectric material 73 only in spaces situated in vertical alignment with the remaining regions of the semiconductor layers 102, 104 based on the second material 14 (FIG. 22). A remaining unfilled empty volume forming a reduced trench 75 is thus made between the two portions 16R, 16L of structure 16 of active zone.

The dielectric region RD separating the first portion 16R provided with a first set of semiconductor regions based on the second material 14 is then formed (FIGS. 23A and 23B) between the second portion 16L provided with a first set of semiconductor regions based on the second material 14.

For this, a conformal deposition of dielectric material 85 and then a CMP planarisation of this dielectric material 85 are typically performed so as to fill the remaining empty volume forming a reduced trench 75 separating the two portions 16R, 16L. Two sets of semiconductor regions facing each other are then separated by this dielectric material 85. Here again, the dielectric and its permittivity are selected so as to promote or not promote coupling in the horizontal direction (parallel to the axis x) between the two arrays of semiconductor regions facing each other.

In the exemplary method embodiment just given, for the implementation of superimposed gates GI, GS, lower gates GI formed from a same material 22 as the upper gates GS are provided. Alternatively, it is however possible to provide different materials between the lower gates GI on the one hand and the upper gates GS on the other hand.

Likewise, in the exemplary embodiment just given, the gates formed against the portion 16R of active zone dedicated, for example, to accommodating quantum dots are based on a same material as those located against the portion 16L of active zone facing it and which is dedicated, for example, to accommodating detection islands.

Alternatively, it is however possible to provide different materials between the gates located against the portion 16R on the one hand and the gates located against the portion 16L on the other hand. Such an alternative can be made to obtain different output works and consequently different operating regimes between, for example, gates controlling quantum dots and gates controlling detection islands. To make such an alternative, one or more lithography steps and one or more additional deposition steps may be provided.

As an alternative to the exemplary method embodiment just given for the implementation of the superimposed gates GI, GS, which describes an approach of the type commonly referred to as “gate-last” in which at least partial replacement of patterns is carried out with a stack having gates separated by an insulation zone, it may be envisaged to make this stack directly.

Thus, according to one alternative embodiment of the gates, a “gate-first” approach can be provided. In this case, directly after the step of forming the structure 16 of active zone described previously in connection with FIGS. 6A-6B, provision can be made for making a stack of layers to form the lower gate, the insulation zone, and then the upper gate. The thicknesses of the conducting or semiconducting layers of gate material(s) and of the insulating layer sandwiched between them are then preferably adjusted as a function of those of the layers of first material 12 and second material 14 of the structure 16 so that each layer of gate material is disposed opposite and in a same plane parallel to the main plane of the substrate as a layer based on the second semiconductor material 14 and in which quantum dots or detection islands are provided.

In either of the exemplary embodiments just described, contact on different gate levels as well as on different semiconductor layer levels can be made, for example, by providing a staircase shape at the ends of the gate structures or portions of active zone.

In a quantum device as described previously, where horizontal interactions are promoted (in other words in directions parallel to the main plane of the substrate) between, on the one hand, a quantum dot BQ1 (respectively BQ2) and, on the other hand, a detection island ID1 (respectively ID2) located in a same horizontal plane as this quantum dot BQ1 (resp. BQ2), a so-called ‘diagonal’ coupling in a diagonal direction DIAG1 (resp. DIAG2) between a quantum dot BQ1 (resp. BQ2) and a detection island ID2 (respectively ID1) located in a different plane to this quantum dot BQ1 (resp. BQ2) can further be desired to be avoided.

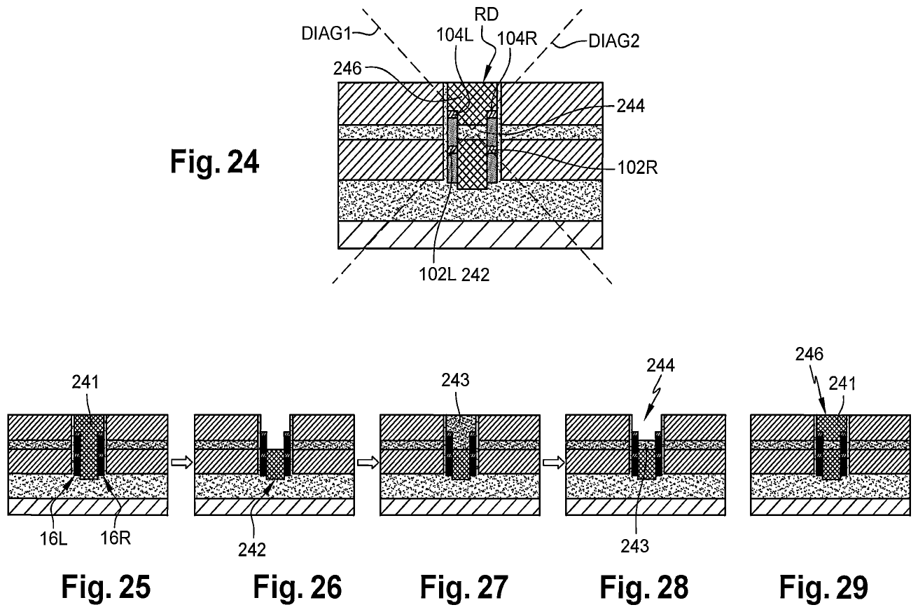

Thus, in an exemplary embodiment illustrated in FIG. 24, a dielectric region RD is thereby provided between the set of semiconductor regions 102R, 104R and the set of semiconductor regions 102L, 104L with herein a heterogeneous composition. A central portion 244 located between a first lower semiconductor region 102R and a second upper semiconductor region 104L and between the first upper semiconductor region 104R and the second lower semiconductor region 102L is based on a dielectric material having a composition and a first relative dielectric permittivity. Another portion 242, of the dielectric region RD located between the first lower semiconductor region 102R and the second lower semiconductor region 102L is provided based on another dielectric material having a composition and a relative dielectric permittivity different from and higher than that of the material of the central portion 244. A portion 246, of the dielectric region RD located this time between the first upper semiconductor region 104R and the second upper semiconductor region 102L is also provided based on a dielectric material having a composition and a relative dielectric permittivity higher than that of the material of the central portion 244.

An exemplary method for making this type of device is illustrated in FIGS. 25 to 28.

A structure as described in connection with

FIG. 22 can first be used. And then (FIG. 25) a dielectric material 241 is deposited so as to fill the space separating the two portions 16R, 16L. This dielectric material 241 can then be planarised, for example by CMP (Chemical Mechanical Planarisation, i.e. chemical mechanical polishing).

The dielectric material 241, for example such as SiN or HfO₂, is then partially removed (FIG. 26) typically by wet etching using H₃PO₄ in the case of SiN or plasma CH₂F₂, SF₆ in the case of SiN, CF₄/Ar in the case of HfO₂ in order to form the lower portion 242 of the insulation region.

Another dielectric material 243 is then deposited, typically with a dielectric permittivity lower than the dielectric permittivity of the dielectric material 241 (FIG. 27). The other dielectric material 243 can be SiO₂, for example, and form the central portion 244 of the dielectric region RD.

A possible planarisation by CMP of this other material 243 is then performed.

In the particular exemplary embodiment illustrated in FIG. 28, partial removal is then carried out, typically by wet etching using HF or CF₄ plasma, of this other material 243 in order to form the central portion 244 of the dielectric region RD.

The dielectric material 241 can then be deposited again to form an upper portion 246 of the dielectric region RD (FIG. 29) which, in this example, has a composition identical to that of the lower portion 242. This dielectric material 241 can then be planarised, for example by CMP.

Alternatively, the upper portion 246 may be formed from a third dielectric material different from that of the portions 242, 244 but with a dielectric permittivity higher than the dielectric permittivity of the dielectric material 243 of the central portion 244.

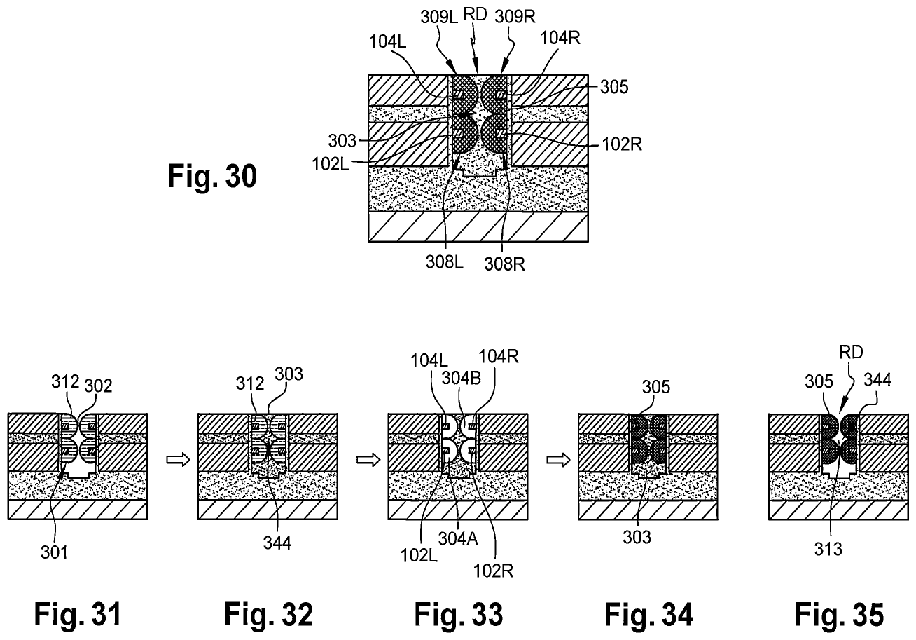

Another example of making a dielectric region RD heterogeneous in terms of dielectric material composition is given in FIG. 30.

The dielectric region RD is herein formed of a dielectric material 305 having a dielectric constant k1 lining each of the first and second lower and upper semiconductor regions 102R, 102L, 104R, 104L, so as to form lower insulating bumps 308R, 308L against the first and second lower semiconductor regions 102R, 102L and upper insulating bumps 309R, 309L against the first and second upper semiconductor regions 102R, 104R.

An insulating space formed between the insulating bumps 308R, 308L 309R, 309L is herein filled with a dielectric material 303 having a second dielectric constant k2 lower than the dielectric constant k1 of the dielectric material 305. A central portion 344 of dielectric material 303 is thus provided to prevent “diagonal” coupling between the semiconductor regions 102L and 104R, and between the semiconductor regions 102R, 104L.

An example method for making this type of device is illustrated in FIGS. 31 to 34.

A structure as described in connection with FIG. 21 obtained after selectively etching the first material 12 in order to release the regions 102R, 102L, 104R, 104L based on the first material 14 can first be used.

First of all (FIG. 31) a semiconductor envelope 301 is formed by epitaxy on the regions 102R, 102L, 104R, 104L based on a sacrificial semiconductor material 312. A semiconductor material 312 is selected to be grown, preferably isotropically, which can be etched selectively with respect to the second material 14. In the particular example illustrated in FIG. 31, this sacrificial semiconductor envelope 301 may be identical to the first material 12, for example SiGe when the material 14 of the regions 102R, 102L, 104R, 104L is silicon. The growth is preferably performed so as to form semiconductor bumps and to maintain a space 302 between semiconductor bumps formed on the first portion 16A of the structure of active zone and the second portion 16B located opposite and separate from the first portion 16A.

This space 302 is then filled with a given dielectric material 303 having a given dielectric constant k2, for example SiO₂ (FIG. 32). This can be made by deposition and then CMP planarisation.

Selective removal of the semiconductor envelope 301 based on sacrificial material 312 is then carried out (FIG. 33). In particular, etching SiGe selectively relative to silicon can be implemented. Such etching leads to the formation of galleries 304A, 304B around the semiconductor regions 102R, 102L, 104R, 104L based on the first material 14.

The galleries 304A, 304B are then filled with a dielectric material 305 of dielectric constant k1, for example SiN or HfO₂ or Al₂O₃. In particular, an ALD (Atomic Layer Deposition) method can be implemented to avoid any filling defects (FIG. 34).

According to one alternative embodiment, a dielectric region RD separating the two portions 16A, 16B of the structure of active zone may be made instead of the dielectric material 303 of dielectric constant k2, with an empty or air-filled space 313 in a central portion 344 of the dielectric region RD and located between the insulating bumps based on the dielectric material 305 of dielectric constant k1. This can further limit the possibility of diagonal coupling between semiconductor regions 102L, 104R and 104L, 102R.

To implement such an alternative, a structure as obtained previously and described in connection with FIG. 34 can first be used, and then the dielectric material 303 of dielectric constant k2 can be selectively removed from the dielectric material 305 of dielectric constant k1. Such selective removal is carried out, for example, using H₃PO₄ when the dielectric material 303 and the dielectric material 305 are SiN and HfO₂ respectively.

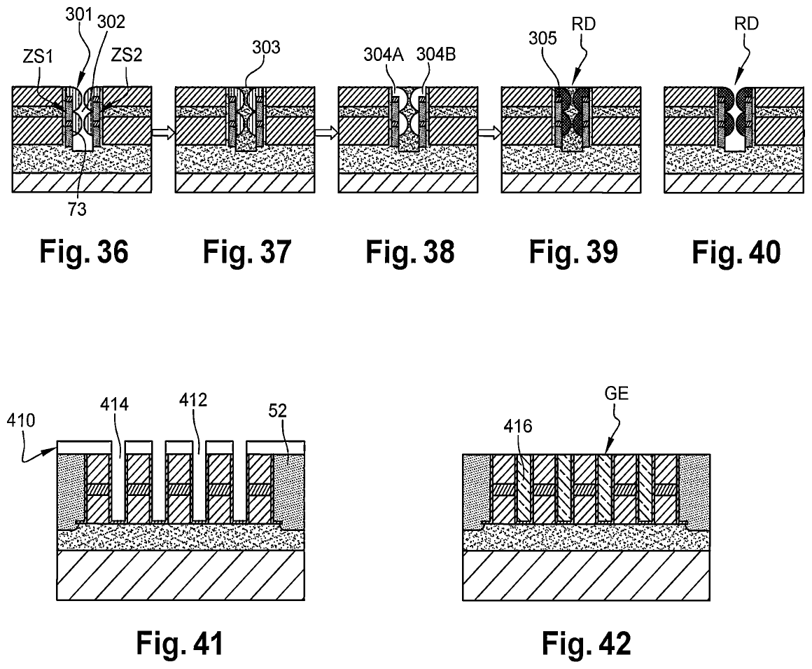

Another exemplary method for making the dielectric region RD between the two portions 16A, 16B of active zone is illustrated in FIGS. 36 to 41.

This time, a structure of the type described in connection with FIG. 22 can first be used to obtain the separation zones ZS1, ZS2 of insulating material 73.

The sacrificial semiconductor envelope 301 is then formed (FIG. 36) by epitaxy on the semiconductor regions 102R, 102L, 104R, 104L.

The dielectric material 303 with dielectric constant k2, for example SiO₂, is then deposited (FIG. 37).

Selective removal of the sacrificial semiconductor envelope 301 based on the first material 12 is then carried out (FIG. 38) so as to form the galleries 304A, 304B around the semiconductor regions 102R, 102L, 104R, 104L based on the first material 14.

The galleries 304A, 304B are then filled with dielectric material 305 of dielectric constant k1, for example SiN or HfO₂ or Al₂O₃, advantageously using an ALD-type deposition method in order to avoid a filling defect (FIG. 39) to form the dielectric region RI of heterogeneous composition.

As with the exemplary embodiment described previously, the dielectric material 303 of dielectric constant k2 can again optionally then be selectively removed (FIG. 40).

As an alternative to either of the above exemplary methods that have just been described, it may be envisaged to make exchange electrodes in inter-gate spaces.

For this, a method illustrated in FIGS. 41 and 42 consists in starting from a structure as obtained after making the gates and described for example previously in connection with FIGS. 19A-19B. A masking 410 is then made, typically of photosensitive resin, in a zone located above the gate block assembly and which includes openings 412 facing inter-gate spaces (FIG. 41). The encapsulating material 52, for example SiO2, located in the inter-gate spaces is then selectively etched relative to the thin spacer layer 33, for example of SiN, in order to form holes 414. A fluorocarbon dry etching method can be used in particular.

After removing the masking 410, depositing a conductive material 416, for example a TiN/W type stack, is performed to fill the holes 414 thus defined (FIG. 42). This deposition is typically followed by a CMP planarisation step. Planarisation is preferably stopped when the top of the structure of active zone is reached (not visible in FIGS. 41 and 42). In this exemplary embodiment, a single exchange electrode GE per inter-gate space is made.

Alternatively, however, it is possible to form superimposed exchange gates which have an arrangement similar to that of the gate electrodes between which these exchange gates are sandwiched. In each inter-gate space, pairs of superimposed exchange gates separated from each other by an insulator can thus be formed. For this, a method similar to that used to make the gates and described previously in connection with FIGS. 15 to 19A-19B can be employed.

1. A Quantum electronic device provided with a substrate (5), the substrate being provided with:
a first set of semiconductor regions (102L, 104L) comprising at least one first lower semiconductor region (102L) and at least one first upper semiconductor region (104L), superimposed on and separated from the first lower semiconductor region via a first so-called “separation” zone (ZS1) of dielectric material,
a second set of semiconductor regions (102R, 104R) comprising at least one second lower semiconductor region (102R) and at least one second upper semiconductor region (104R), superimposed on, and separated from, the second lower semiconductor region via a second so-called “separation” zone (ZS2) of dielectric material,
the first set of semiconductor regions (102L, 104L) being disposed opposite the second set of semiconductor regions (102R, 104R) so that the first lower semiconductor region (102L) is disposed facing the second lower semiconductor region (102R) and so that the first upper semiconductor region (104L) is disposed facing the second upper semiconductor region (104R),
at least one dielectric region (RD) separating the first set of semiconductor regions (102R, 104R) from the second set of semiconductor regions (102R, 104R),
the device further comprising:
a first group of superimposed gates (GI1, GS1) comprising at least a first lower gate (GI1) and a first upper gate (GS1) superimposed on and separated from the first lower gate by a first insulation zone (ZI1), the first lower gate (GI1) and the first upper gate (GS1) being disposed against, and facing, respectively, the first lower semiconductor region (102L) and the first upper semiconductor region (104L) so as to exert electrostatic control of the first lower semiconductor region and the first upper semiconductor region, respectively,
a second group of superimposed gates (GI2, GS2) comprising at least one second lower gate (GI2) separated from a second upper gate (GS2) superimposed on, and separated from, the second lower gate by a second insulation zone (ZI2), the second lower gate (GI2) and the second upper gate (GS2) being disposed against, and facing, respectively of the second lower semiconductor region (102R) and of the second upper semiconductor region (104R) so as to exert electrostatic control of the second lower semiconductor region (102R) and of the second upper semiconductor region (104R) respectively, the first group of superimposed gates and the second group of superimposed gates being disposed on either side of the first set of semiconductor regions and of the second set of semiconductor regions.

2. The quantum electronic device according to claim 1, wherein said dielectric region (RD) is provided so as to allow electrostatic coupling between the first lower semiconductor region (102L) and the second lower semiconductor region (102R), and so as to allow electrostatic coupling between the first upper semiconductor region (104L) and the second upper semiconductor region (104R),
or
wherein said separation zones (ZS1, ZS2) are provided so as to allow electrostatic coupling between the first lower semiconductor region (102L) and the first upper semiconductor region (104L), and so as to allow electrostatic coupling between the second lower semiconductor region (102R) and the second upper semiconductor region (102L),
or
wherein said dielectric region (RD) is provided so as to allow electrostatic coupling between the first lower semiconductor region (102L) and the second lower semiconductor region (102R), and so as to allow electrostatic coupling between the first upper semiconductor region (104L) and the second upper semiconductor region (104R),
said separation zones (ZS1, ZS2) being further provided so as to allow electrostatic coupling between the first lower semiconductor region (102L) and the first upper semiconductor region (104L), and so as to allow electrostatic coupling between the second lower semiconductor region (102R) and the second upper semiconductor region (102L).

3. The quantum electronic device according to claim 1, wherein the first lower semiconductor region (102L) and the first upper semiconductor region (104L) are regions of a lower semiconductor bar (102) and an upper semiconductor bar (104) respectively, the lower semiconductor bar and the upper semiconductor bar extending in parallel to a first direction (y) parallel to a main plane of the substrate,
the device being provided with a third group of superimposed gates (GI3, GS3) juxtaposed to said first group of gates (GI1, GS1) and wherein the third group of superimposed gates (GI3, GS3) comprises at least a third lower gate (GI3) separated from a third upper gate (GS3) superimposed to, and separated from, the third lower gate by a third insulating zone, the third lower gate (GI3) and the third upper gate (GS3) being disposed against, and facing, a third lower semiconductor region (102L2) of the lower semiconductor bar (102) and a third upper semiconductor region (104L2) of the upper semiconductor bar (104) respectively to control them electrostatically.

4. The quantum electronic device according to claim 3, wherein said lower semiconductor bar (102) and said upper semiconductor bar (104) are a first lower semiconductor bar and a first upper semiconductor bar, respectively, the second lower semiconductor region (102R) and the second upper semiconductor region (104R) being regions of a second lower semiconductor bar and a second upper semiconductor bar, respectively, said second lower and upper semiconductor bars extending in parallel to said first lower (102) and upper (104) semiconductor bars, respectively, the device being provided with a fourth group (GI4, GS4) of superimposed gates juxtaposed to said second group of superimposed gates for electrostatic control of a fourth semiconductor region of the second lower semiconductor bar (102) and a fourth upper semiconductor region of the second upper semiconductor bar (104), the first lower semiconductor bar (102) and the second lower semiconductor bar (102′) being located in a same first plane (P1) parallel to a main plane of the substrate, the first upper semiconductor bar and the second upper semiconductor bar being situated in the same second plane (P2) parallel to a main plane of the substrate, the third lower semiconductor region being disposed facing the fourth lower region, the third upper semiconductor region being disposed facing the fourth upper semiconductor region.

5. The device according to claim 4, further comprising, in a direction parallel to the first direction (y), between said first group of gates (GI1, GS1) and said third group of gates (GI3, GS3):
at least one exchange electrode (GE) or
superimposed exchange electrodes (GE11, GE12) separated from each other by an insulating separation layer (CSI),
a zone of at least one insulating material (53).

6. The device according to claim 1, wherein the device further comprises:
a doped semiconductor block, forming a first dopant reservoir (DT1), the doped semiconductor block being arranged at a first end of the first upper semiconductor bar, the first lower semiconductor bar, the second upper semiconductor bar and the second lower semiconductor bar,
another doped semiconductor block, forming a second dopant reservoir (DT2), the other doped semiconductor block being arranged at a second end of the first upper semiconductor bar, the first lower semiconductor bar, the second upper semiconductor bar, the second lower semiconductor bar, and which is opposite to the first end.

7. The device according to claim 1, wherein the dielectric region (RD) between the first set of semiconductor regions (102L, 104L) and the second set of semiconductor regions (102R, 104R) is provided with a heterogeneous dielectric composition such that in a central portion (244, 303) located between the first lower semiconductor region and the second upper semiconductor region and between the first upper semiconductor region and the second lower semiconductor region, the dielectric region (RD) has a first composition and a first relative dielectric permittivity, and that in another portion (242, 246) located between the first lower semiconductor region and the second lower semiconductor region or between the first upper semiconductor region and the second upper semiconductor region, the dielectric region (RD) has a second composition and a second relative dielectric permittivity higher than the first relative dielectric permittivity.

8. A method for manufacturing a quantum device according to claim 1, wherein forming said first set of semiconductor regions (102L, 104L) and said second set (102R, 104R) of semiconductor regions comprises steps of:
making on said substrate (10) a structure (16) formed of a superimposition of layers (10₁,10₂,10₃,10₄,10₅) comprised of alternating layers (10₁,10₃,10₅) based on a given first material (12) and layers (10₂,10₄) based on a second material, the second material being semiconductor, said given first material being able to be etched selectively with respect to said given second material,
making a separation trench (65) mainly extending in a direction parallel to the first direction by etching said superimposition of layers so as to divide said structure into a first portion (16A) and a second portion (16B), the first portion (16A) and the second portion (16B) extending in parallel to the first direction, the semiconductor regions of said first set being semiconductor regions of the first portion and formed from said given second material, the semiconductor regions of said second set being semiconductor regions of the second portion and formed from said given second material.

9. The method for manufacturing a quantum device according to claim 8, further comprising, after making said trench (65), forming said dielectric region (RD) by depositing one or more dielectric materials (85) between said first portion (16A) and said second portion (16B) of said structure (16).

10. The method for manufacturing a quantum device according to claim 8, further comprising, after making the separation trench and prior to forming said dielectric region (RD), steps of:
at least partially etching said given first material (12) selectively with respect to the second material (14) in the first portion (16A) and said second portion (16B) so as to release spaces (71),
filling said spaces (71) with a dielectric material (73) to form the first “separation” zone (ZS1) and the second “separation” zone (ZS2).

11. The method according to claim 10, further comprising, after filling said spaces (71) with a given dielectric material (73), steps of:
anisotropically etching the dielectric material so as to release a space forming a reduced trench (75) between said portions (16A, 16B) of active zone,
filling the reduced trench (75) by means of at least one other dielectric material different from said given dielectric material.

12. The method according to claim 8, further comprising, after forming said structure (16) and prior to forming said separation trench in this structure (16), steps of:
forming gate patterns of gate material on either side of the structure,
forming an insulating encapsulation (52) around the gate patterns,
partially removing the gate material so as to retain a lower block (GI) of gate material and making cavities (54) above this lower block of gate material and that are surrounded by the encapsulation (52),
filling the cavities with at least one insulating layer so as to form an insulation zone (ZI) on the lower block of gate material and then,
filling the cavities with at least one layer of gate material, so as to form an upper block (GS) of gate material on the insulation zone (ZI).

13. The method for manufacturing a quantum device according to claim 11, further comprising,
after forming said structure (16) and prior to forming said separation trench (65) in this structure, forming dopant reservoirs at ends of said structure, forming said dopant reservoirs comprising:
performing partial etching of the first material (12) selectively with respect to the second material (14) in order to create recesses (41) at said ends of said structure (16),
filling said recesses (41) with an insulating material in order to form insulating plugs (43) in said recesses,
performing epitaxy of semiconductor material (48) from uncovered ends of the layers (10₂,10₄) based on the second material (14), while the layers (10₂,10₄) based on the first material (12) are protected by the insulating plugs (43).
